(19) United States
(12) Patent Application Publication
(10) Pub. No.: US 2026/0282386 A1
(43) Pub. Date: Sep. 17, 2026

(54) MAGNETIC MEMORY DEVICE

(71) Applicants: Kioxia Corporation, Tokyo (JP); SK hynix Inc., Icheon-si (KR)

(72) Inventors: Takuya SHIMANO, Seoul (KR); Kenichi YOSHINO, Seongnam-si Gyeonggi-do (KR); Yuichi ITO, Seoul (KR); Daehee LEE, Icheon-si Gyeonggi-do (KR); Bokyung JUNG, Icheon-si Gyeonggi-do (KR); Eunkyo BYUN, Icheon-si Gyeonggi-do (KR)

(73) Assignees: Kioxia Corporation, Tokyo (JP); SK hynix Inc., Icheon-si (KR)

(21) Appl. No.: 19/325,076

(22) Filed: Sep. 10, 2025

(30) Foreign Application Priority Data
Mar. 17, 2025 (JP) 2025-042279

(51) Int. Cl. H10B 61/00; H10N 50/01; H10N 50/10

(52) U.S. Cl. CPC H10B 61/10; H10N 50/01; H10N 50/10

(57) ABSTRACT

According to one embodiment, a magnetic memory device includes first and second lower wiring lines, each extending along a first direction, first and second upper wiring lines, each extending along a second direction, a first memory cell between the first lower and first upper wiring line, a second memory cell between the first lower and second upper wiring line, and a third memory cell between the second lower and first upper wiring line, and each of the first, second, and third memory cells includes a structure in which a magnetoresistance effect element and a switching element are stacked in a third direction, the magnetoresistance effect element includes main body and a sidewall, and the sidewall included in the first and second memory cells are spaced apart from each other along the first direction.

### CROSS-REFERENCE TO RELATED APPLICATIONS

This application is based upon and claims the benefit of priority from Japanese Patent Application No. 2025-042279, filed Mar. 17, 2025, the entire contents of which are incorporated herein by reference.

### FIELD

Embodiments described herein relate generally to a magnetic memory device.

### BACKGROUND

Magnetic memory devices in which a plurality of memory cells each including a magnetoresistance effect element and a selector (switching element) are integrated on a semiconductor substrate, have been proposed.

### BRIEF DESCRIPTION OF THE DRAWINGS

FIG. 1 is a perspective view schematically showing a basic configuration of a magnetic memory device according to the first embodiment.

FIG. 2A is a cross-sectional view schematically showing a detailed configuration of the magnetic memory device according to the first embodiment.

FIG. 2B is another cross-sectional view schematically showing the detailed configuration of the magnetic memory device according to the first embodiment.

FIG. 3A is a cross-sectional view schematically showing an example of a basic configuration of a magnetoresistance effect element main body of magnetic memory device according to the first embodiment.

FIG. 3B is a cross-sectional view schematically showing another example of the basic configuration of the main body portion of the magnetoresistance effect element contained in the magnetic memory device according to the first embodiment.

FIG. 4A is a cross-sectional view schematically showing a part of a method of manufacturing the magnetic memory device according to the first embodiment.

FIG. 4B is a cross-sectional view schematically showing the part of the method of manufacturing the magnetic memory device according to the first embodiment.

FIG. 5A is a cross-sectional view schematically showing another part of the method of manufacturing the magnetic memory device according to the first embodiment.

FIG. 5B is a cross-sectional view schematically showing another part of the method of manufacturing the magnetic memory device according to the first embodiment.

FIG. 6A is a cross-sectional view schematically showing still another part of the method of manufacturing the magnetic memory device according to the first embodiment.

FIG. 6B is a cross-sectional view schematically showing still another part of the method of manufacturing the magnetic memory device according to the first embodiment.

FIG. 7A is a cross-sectional view schematically showing still another part of the method of manufacturing the magnetic memory device according to the first embodiment.

FIG. 7B is a cross-sectional view schematically showing still another part of the method of manufacturing the magnetic memory device according to the first embodiment.

FIG. 8A is a cross-sectional view schematically showing still another part of the method of manufacturing the magnetic memory device according to the first embodiment.

FIG. 8B is a cross-sectional view schematically showing still another part of the method of manufacturing the magnetic memory device according to the first embodiment.

FIG. 9A is a cross-sectional view schematically showing still another part of the method of manufacturing the magnetic memory device according to the first embodiment.

FIG. 9B is a cross-sectional view schematically showing still another part of the method of manufacturing the magnetic memory device according to the first embodiment.

FIG. 10A is a cross-sectional view schematically showing a detailed configuration of a magnetic memory device according to the second embodiment.

FIG. 10B is a cross-sectional view schematically showing the detailed configuration of the magnetic memory device according to the second embodiment.

FIG. 11A is a cross-sectional view schematically showing a part of a method of manufacturing the magnetic memory device according to the second embodiment.

FIG. 11B is a cross-sectional view schematically showing a part of the method of manufacturing the magnetic memory device according to the second embodiment.

FIG. 12A is a cross-sectional view schematically showing still another part of the method of manufacturing the magnetic memory device according to the second embodiment.

FIG. 12B is a cross-sectional view schematically showing still another part of the method of manufacturing the magnetic memory device according to the second embodiment.

FIG. 13A is a cross-sectional view schematically showing still another part of the method of manufacturing the magnetic memory device according to the second embodiment.

FIG. 13B is a cross-sectional view schematically showing still another part of the method of manufacturing the magnetic memory device according to the second embodiment.

FIG. 14A is a cross-sectional view schematically showing still another part of the method of manufacturing the magnetic memory device according to the second embodiment.

FIG. 14B is a cross-sectional view schematically showing still another part of the method of manufacturing the magnetic memory device according to the second embodiment.

FIG. 15A is a cross-sectional view schematically showing still another part of the method of manufacturing the magnetic memory device according to the second embodiment.

FIG. 15B is a cross-sectional view schematically showing still another part of the method of manufacturing the magnetic memory device according to the second embodiment.

FIG. 16A is a cross-sectional view schematically showing still another part of the method of manufacturing the magnetic memory device according to the second embodiment.

FIG. 16B is a cross-sectional view schematically showing still another part of the method of manufacturing the magnetic memory device according to the second embodiment.

### DETAILED DESCRIPTION

In general, according to one embodiment, a magnetic memory device includes a first lower wiring line and a second lower wiring line, each extending along a first direction and adjacent to each other, a first upper wiring line and a second upper wiring line, each extending along a second direction which intersects the first direction and adjacent to each other, a first memory cell provided between the first lower wiring line and the first upper wiring line, a second memory cell provided between the first lower wiring line and the second upper wiring line, and a third memory cell provided between the second lower wiring line and the first upper wiring line, and each of the first, second, and third memory cells includes a structure in which a magnetoresistance effect element and a switching element provided on a lower layer side of the magnetoresistance effect element are stacked in a third direction which intersects the first and second directions, the magnetoresistance effect element includes a magnetoresistance effect element main body and a sidewall insulating layer provided on a side wall of the magnetoresistance effect element main body, and the sidewall insulating layer of the magnetoresistance effect element included in the first memory cell and the sidewall insulating layer of the magnetoresistance effect element included in the second memory cell are spaced apart from each other along the first direction.

Embodiments will now be described with reference to the accompanying drawings.

### First Embodiment

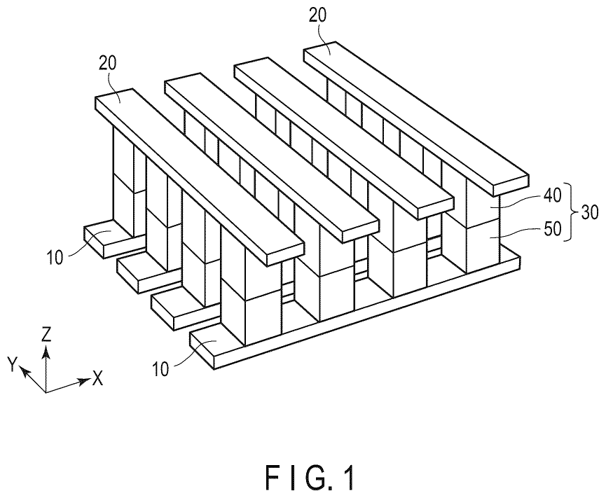

FIG. 1 is a perspective view schematically illustrating a basic configuration of a magnetic memory device according to the first embodiment.

As shown in FIG. 1, the magnetic memory device of this embodiment includes a plurality of lower wiring lines 10 each extending along an X direction, a plurality of upper wiring lines 20 each extending in a Y direction, and a plurality of memory cells 30 each provided between a respective one of the lower wiring lines 10 and a respective one of the upper wiring lines 20.

The lower wiring lines 10 and upper wiring lines 20 are formed of a metal material such as tungsten (W). One of the groups of the lower wiring lines 10 and upper wiring lines 20 corresponds to word lines, and the other group of the lower wiring lines 10 and upper wiring lines 20 corresponds to bit lines.

Each of the memory cells 30 includes a magnetoresistance effect element 40 and a selector (switching element) 50 provided on the lower layer side of the magnetoresistance effect element 40, and has a structure in which the magnetoresistance effect element 40 and the selector 50 are stacked along the Z direction.

Note that the X direction, Y direction, and Z direction are mutually intersecting directions. Specifically, the X direction, Y direction, and Z direction are orthogonal to each other.

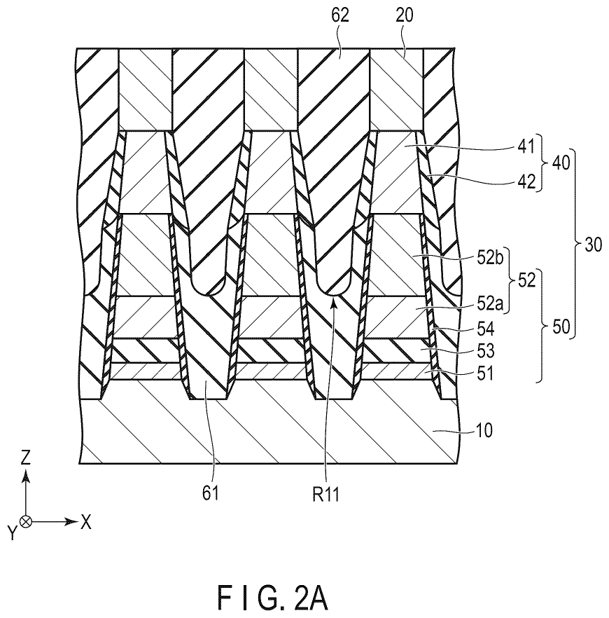

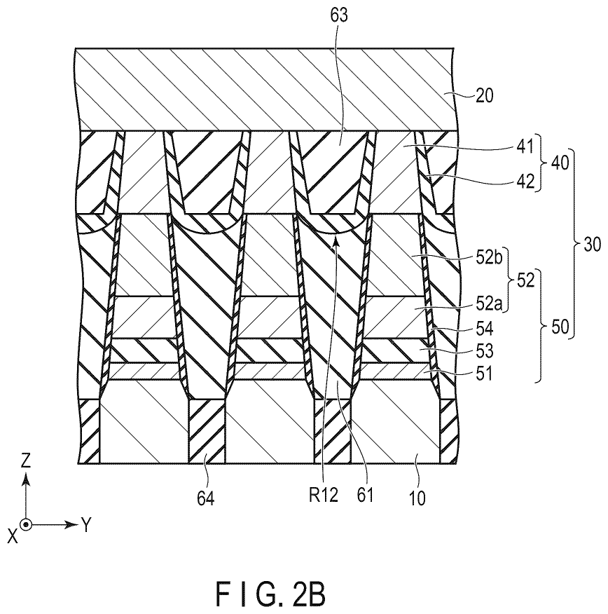

FIGS. 2A and 2B are sectional views each schematically illustrating a detailed configuration of the magnetic memory device of this embodiment. FIG. 2A is a sectional view taken along the X direction, and FIG. 2B is a sectional view taken along the Y direction.

The magnetic memory device shown in FIGS. 2A and 2B is provided on an under structure (not shown) including a semiconductor substrate (not shown) and the like, and as already described, includes a plurality of lower wiring lines 10, a plurality of upper wiring lines 20, and a plurality of memory cells 30 each provided between the respective one of the lower wiring lines 10 and the respective one of the upper wiring lines 20.

As described above, each memory cell 30 includes a magnetoresistance effect element 40 and a selector 50, and the magnetoresistance effect element 40 and the selector 50 are stacked along the Z direction.

The magnetoresistance effect element 40 includes a magnetoresistance effect element main body 41 and a sidewall insulating layer 42 provided on the side wall of the magnetoresistance effect element main body 41.

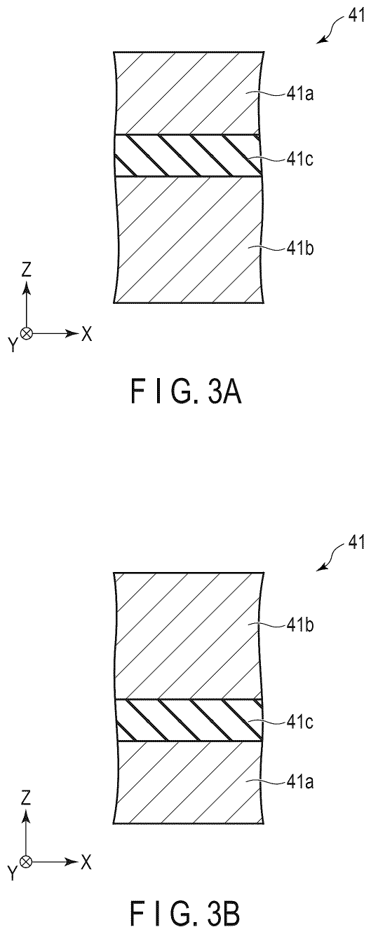

FIG. 3A is a cross-sectional view schematically illustrating an example of the basic configuration of the magnetoresistance effect element main body 41.

The magnetoresistance effect element main body 41 is a magnetic tunnel junction (MTJ) element including a storage layer (first magnetic layer) 41a, a reference layer (second magnetic layer) 41b, and a tunnel barrier layer (nonmagnetic layer) 41c.

The storage layer 41a is a ferromagnetic layer having a variable magnetization direction, and is formed, for example, of a CoFeB layer containing cobalt (Co), iron (Fe), and boron (B). The term “variable magnetization direction” means that the magnetization direction changes for a predetermined write current.

The reference layer 41b is a ferro magnetic layer having a fixed magnetization direction, and is formed, for example, of a CoFeB layer containing cobalt (Co), iron (Fe), and boron (B), and a superlattice layer of platinum (Pt) and cobalt (Co). The term “fixed magnetization direction” means that the magnetization direction does not change for a predetermined write current.

The tunnel barrier layer 41c is an insulating layer provided between the storage layer 41a and the reference layer 41b, and is formed of an MgO layer containing magnesium (Mg) and oxygen (O), for example.

When the magnetization direction of the storage layer 41a is parallel to the magnetization direction of the reference layer 41b, the magnetoresistance effect element main body 41 exhibits a low-resistance state having relatively low resistance. On the other hand, when the magnetization direction of the storage layer 41a is antiparallel to the magnetization direction of the reference layer 41b, the magnetoresistance effect element main body 41 exhibits a high-resistance state having relatively high resistance. With this configuration, the magnetoresistance effect element 40 can store binary data in accordance with the resistance state.

The magnetoresistance effect element 40 described above is a spin transfer torque (STT) type magnetoresistance effect element having perpendicular magnetization.

FIG. 3B is a cross-sectional view schematically illustrating another example of the basic configuration of the magnetoresistance effect element main body 41.

The magnetoresistance effect element main body 41 shown in FIG. 3A is a top-free type element in which the storage layer 41a is located on the upper layer side of the reference layer 41b. Note here that as shown in FIG. 3B, a bottom-free type element may as well be used in which the storage layer 41a is located on the lower layer side of the reference layer 41b.

Let us return to the description of FIGS. 2A and 2B. As already mentioned, the magnetoresistance effect element 40 includes a sidewall insulating layer 42 provided on the side wall of the magnetoresistance effect element main body 41. The sidewall insulating layer 42 functions as a protective film for the magnetoresistance effect element main body 41, and it surrounds the side wall of the magnetoresistance effect element main body 41 and covers all the side wall of the magnetoresistance effect element main body 41. The sidewall insulating layer 42 is formed, for example, of silicon nitride.

For simplicity of explanation, lower wiring lines 10 adjacent to each other along the Y direction are referred to as first and second lower wiring lines 10, and upper wiring lines 20 adjacent to each other along the X direction are referred to as first and second upper wiring lines 20. Further, the memory cell 30 provided between the first lower wiring line 10 and the first upper wiring line 20 is referred to as a first memory cell 30, the memory cell 30 provided between the first lower wiring line 10 and the second upper wiring line 20 is referred to as a second memory cell 30, and the memory cell 30 provided between the second lower wiring line 10 and the first upper wiring line 20 is referred to as a third memory cell 30.

As shown in FIG. 2A, the sidewall insulating layer 42 of the magnetoresistance effect element 40 included in the first memory cell 30 and the sidewall insulating layer 42 of the magnetoresistance effect element 40 included in the second memory cell 30 are spaced apart from each other along the X direction. That is, the sidewall insulating layers 42 of the magnetoresistance effect elements 40 that are adjacent to each other along the X direction are spaced apart (separated) from each other along the X direction.

As shown in FIG. 2B, the sidewall insulating layer 42 of the magnetoresistance effect element 40 included in the first memory cell 30 and the sidewall insulating layer 42 of the magnetoresistance effect element 40 included in the third memory cell 30 are continuously provided along the Y direction. That is, the sidewall insulating layers 42 of the magnetoresistance effect elements 40 that are adjacent to each other along the Y direction are continuously provided along the Y direction (not separated from each other along the Y direction).

The selector 50 is a two-terminal switching element, and includes a bottom electrode 51, a top electrode 52, a selector material layer (switching material layer) 53 disposed between the bottom electrode 51 and the top electrode 52, and a sidewall insulating layer 54 disposed on the sidewall of the bottom electrode 51, the top electrode 52, and the selector material layer 53.

The bottom electrode 51 is formed, for example, of a titanium nitride (TiN) layer. The top electrode 52 is formed, for example, of a carbon (C) layer 52a and a titanium nitride (TiN) layer 52b, and also functions as a bottom electrode for the magnetoresistance effect element 40. The selector material layer 53 is formed from a predetermined material whose internal state changes according to an applied voltage. The sidewall insulating layer 54 is formed, for example, of silicon nitride.

The selector 50 has the characteristic of changing from an off state to an on state when a voltage equal to or greater than a threshold voltage is applied between the bottom electrode 51 and the top electrode 52.

When a voltage is applied between the lower wiring line 10 and the upper wiring line 20, and a voltage equal to or higher than the threshold voltage is applied between the bottom electrode 51 and the top electrode 52 of the selector 50, the selector 50 is set to the on state, thus making it possible to perform a write or read on the magnetoresistance effect element 40.

Insulating layers 61, 62, 63, and 64 are provided around the configuration described above.

As shown in FIGS. 2A and 2B, the insulating layer (first insulating layer) 61 is provided so as to surround a plurality of selectors 50. With this configuration, the side surface of each of the selectors 50 is surrounded by the insulating layer 61. The insulating layer 61 is formed from a material different from that of the sidewall insulating layer 42. For example, the insulating layer 61 is formed of silicon oxide.

As shown in FIG. 2A, the portion of the insulating layer 61, which is located between the selector 50 included in the first memory cell 30 and the selector 50 included in the second memory cell 30 has a recess portion (first recess portion) R11 that is recessed in the Z direction. That is, the portion of the insulating layer 61 located between selectors 50 that are adjacent to each other along the X direction has the recess portion R11. The recess portion R11 extends continuously in the Y direction, and as viewed from the Z direction, the recess portion R11 extends continuously in the Y direction in the area between the respective upper wiring lines 20 adjacent to each other.

As shown in FIG. 2B, the portion of the insulating layer 61 located between the selector 50 included in the first memory cell 30 and the selector 50 included in the third memory cell 30 has a recess portion (second recess portion) R12 that is recessed in the Z direction. That is, the portion of the insulating layer 61 located between the selectors 50 that are adjacent to each other along the Y direction has the recess portion R12.

As shown in FIGS. 2A and 2B, the depth of the recess portion R11 is greater than the depth of the recess portion R12. Note that the recess portion R12 does not necessarily have to be provided, and the insulating layer 61 may as well be provided in a flat state at the position corresponding to the position where the recess portion R12 is provided.

As shown in FIG. 2A, the insulating layer (second insulating layer) 62 includes a portion that fills the recess portion R11 of the insulating layer 61. Further, the insulating layer 62 further includes a portion located between the magnetoresistance effect element 40 included in the first memory cell 30 and the magnetoresistance effect element 40 included in the second memory cell 30, and further includes a portion located between the first upper wiring line 20 and the second upper wiring line 20. That is, the insulating layer 62 further includes a portion located between magnetoresistance effect elements 40 that are adjacent to each other along the X direction and a portion located between upper wiring lines 20 that are adjacent to each other along the X direction. The insulating layer 62 is formed, for example, from a low-dielectric-constant material such as silicon oxide and silicon nitride. Further, a void portion may be provided between the insulating layer 62 and the insulating layer 61.

As shown in FIG. 2B, the insulating layer 63 includes a portion located between the magnetoresistance effect element 40 included in the first memory cell 30 and the magnetoresistance effect element 40 included in the third memory cell 30. That is, the insulating layer 63 includes a portion located between magnetoresistance effect elements 40 that are adjacent to each other along the Y direction. The insulating layer 63 is formed, for example, of silicon oxide.

As shown in FIG. 2B, the insulating layer 64 includes a portion located between lower wiring lines 10 that are adjacent to each other along the Y direction. The insulating layer 64 is formed, for example, of silicon oxide.

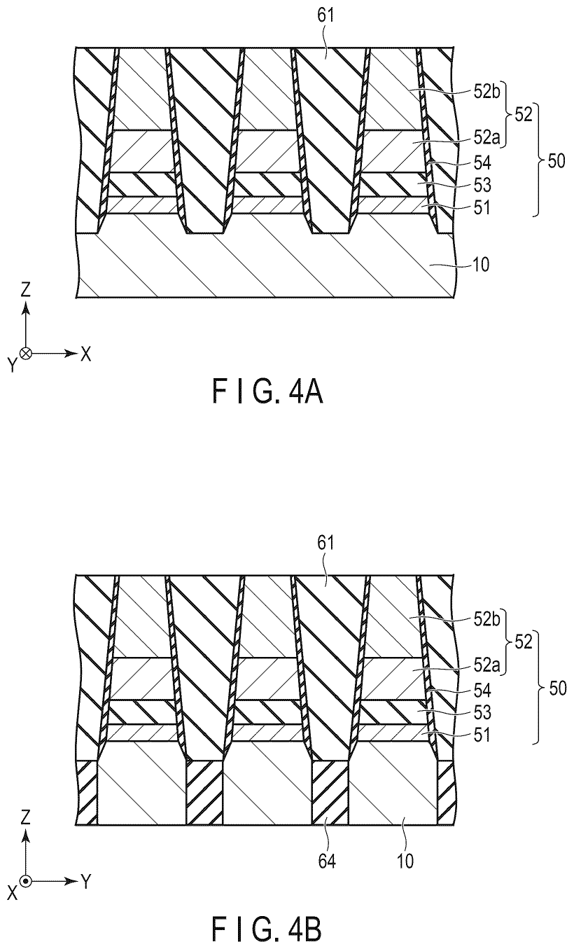

Next, a method of manufacturing the magnetic memory device according to this embodiment will be described with reference to FIGS. 4A and 4B to 9A and 9B. FIGS. 4A to 9A are cross-sectional views taken along the X direction, and FIGS. 4B to 9B are sectional views taken along the Y direction.

First, as shown in FIGS. 4A and 4B, a configuration including a plurality of lower wiring lines 10, a plurality of selectors 50, an insulating layer 61, and an insulating layer 64 is formed on an under structure (not shown). More specifically, a plurality of selectors 50 are formed on the configuration including a plurality of lower wiring lines 10 and the insulating layer 64, and the insulating layer 61 is formed to surround the plurality of selectors 50.

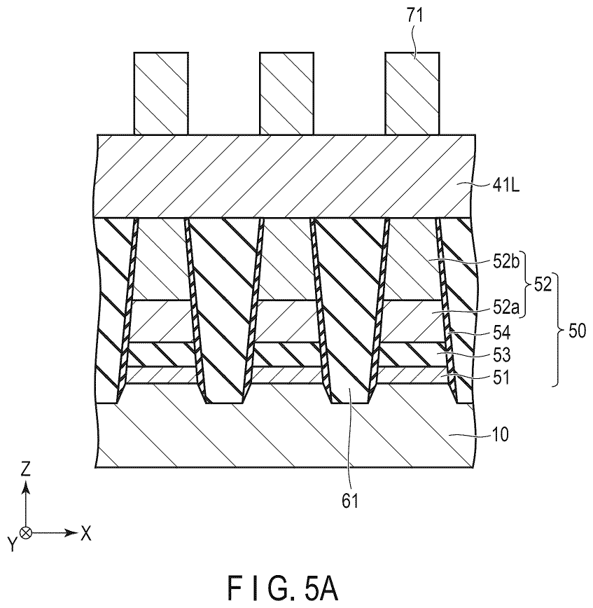

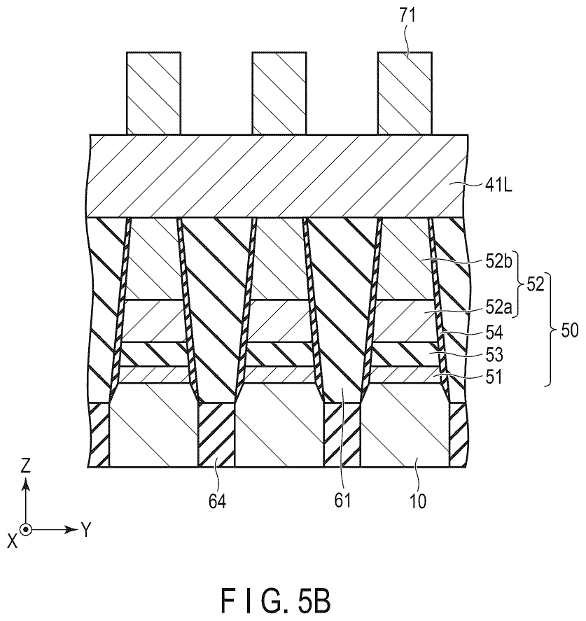

Next, as shown in FIGS. 5A and 5B, a magnetoresistance effect element layer 41L is formed on the configuration obtained in FIGS. 4A and 4B. Further, a hard mask 71 is formed on the magnetoresistance effect element layer 41L.

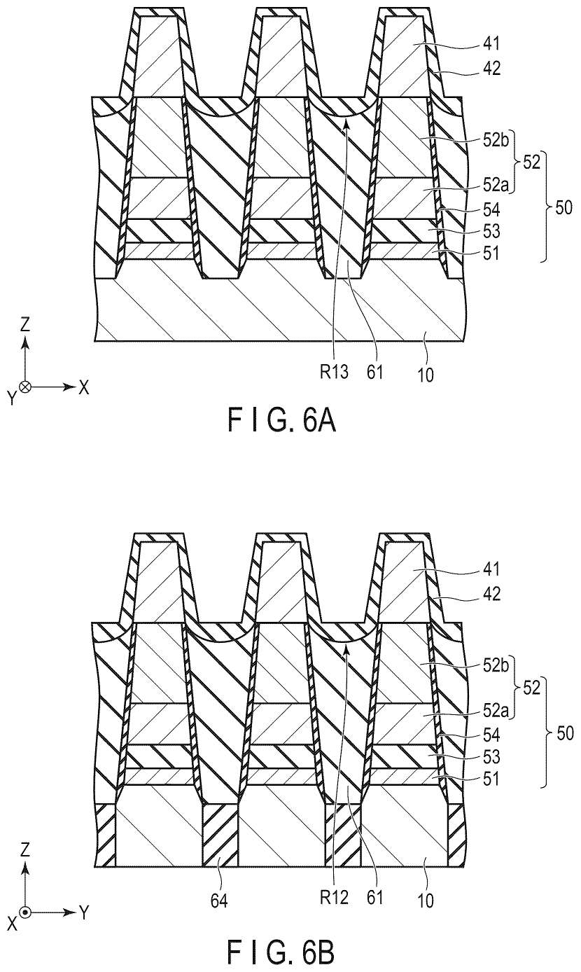

Next, as shown in FIGS. 6A and 6B, the magnetoresistance effect element layer 41L is etched using the hard mask 71 as a mask by ion beam etching (IBE) so as to form a pattern of the magnetoresistance effect element main body 41. In this embodiment, the surface of the insulating layer 61 is also etched during the etching process, and thus recesses including recess portions R12 and R13 are formed in the insulating layer 61. Note here that when the surface of the insulating layer 61 is excessively etched, the magnetoresistance effect element main body 41 and the selector 50 may as well be undesirably damaged. For this reason, it is unpreferable to form deep recesses. As a result, residues of the material contained in the magnetoresistance effect element main body 41 may remain on the surface of the insulating layer 61. Subsequently, a sidewall insulating layer 42 is formed so as to cover the magnetoresistance effect element main body 41 and the insulating layer 61.

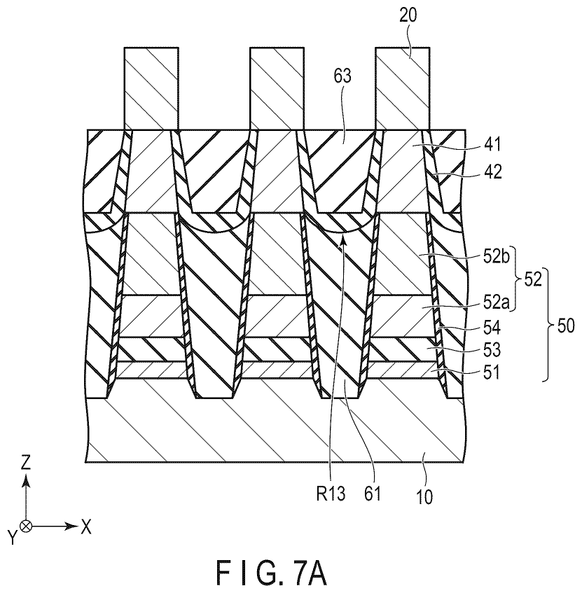

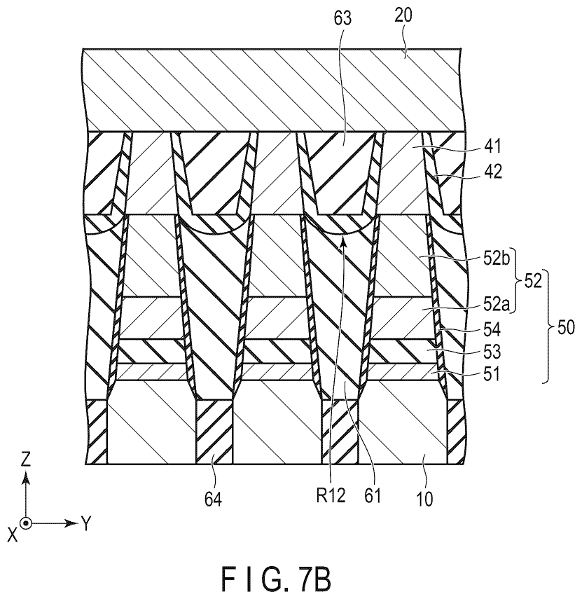

Next, as shown in FIGS. 7A and 7B, an insulating layer 63 is formed on the configuration obtained in the step of FIGS. 6A and 6B, and then the insulating layer 63 is planarized. Further, a plurality of upper wiring lines 20 are formed on the configuration thus obtained.

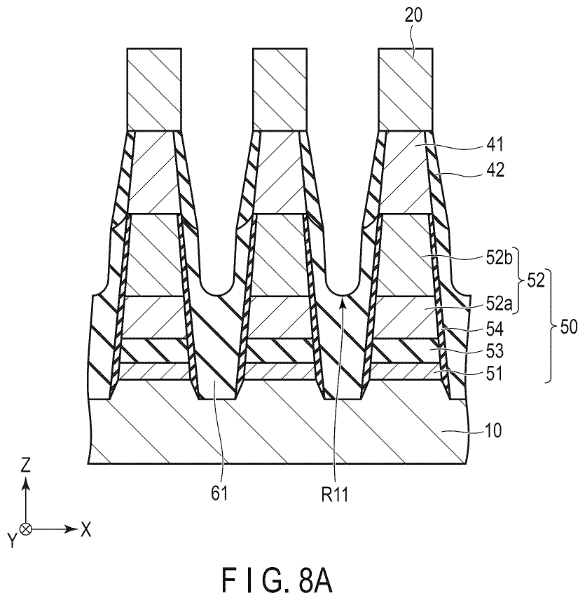

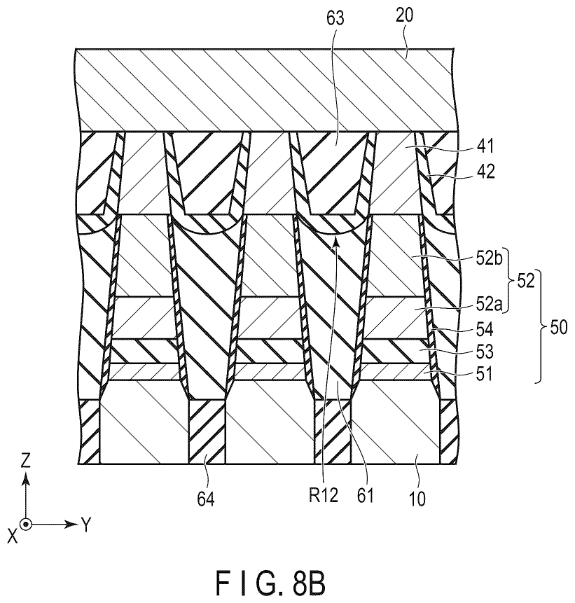

Next, as shown in FIGS. 8A and 8B, the upper wiring lines 20 are used as a mask, and the insulating layer 63, sidewall insulating layer 42, and insulating layer 61 are etched using reactive ion etching (RIE) or the like. At this time, the etching is performed under the conditions that the etching rate of the sidewall insulating layer 42 is higher than that of the upper wiring lines 20, and the etching rates of the insulating layers 61 and 63 are higher than that of the sidewall insulating layer 42. With this condition, the insulating layer 63 can be sufficiently etched without substantially etching the upper wiring lines 20 and the sidewall insulating layer 42, and thus it is possible to reliably separate adjacent upper wiring lines 20 from each other. Further, a sufficiently deep recess portion R11 can be formed in the insulating layer 61, thereby making it possible to reliably remove the residual material remaining, if any, on the surface of the insulating layer 61 during the processing step shown in FIGS. 6A and 6B. In this manner, it is possible to prevent electrical conduction contact caused by the residual material, between magnetoresistance effect elements 40 that are adjacent to each other along the X direction.

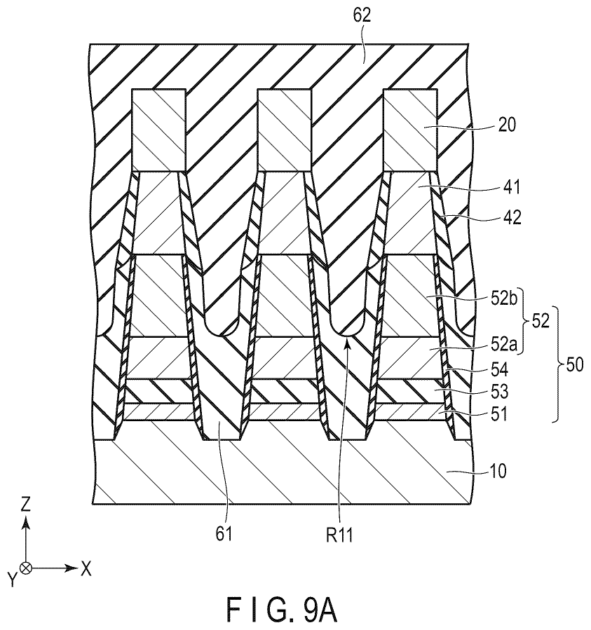

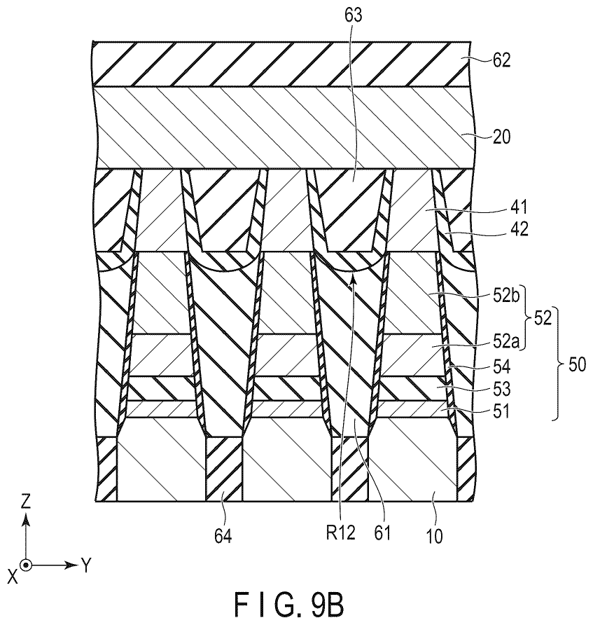

Next, as shown in FIGS. 9A and 9B, an insulating layer 62 is formed on the configuration obtained in the processing step of FIGS. 8A and 8B, and the recess portion R11 is filled with the insulating layer 62.

Thereafter, the insulating layer 62 is planarized, and thus a magnetic memory device having such a configuration as shown in FIGS. 4A and 4B is formed.

As described above, in this embodiment, in the step shown in FIGS. 8A and 8B, a plurality of upper wiring lines 20 are used as a mask to etch the insulating layer 63, the sidewall insulating layer 42, and the insulating layer 61. With this process, the insulating layer 63 is sufficiently etched, thereby making it possible to reliably separate adjacent upper wiring lines 20 from each other. As a result, magnetoresistance effect elements 40 adjacent to each other along the X direction can be electrically separated reliably from each other. Further, the sufficiently deep recess portion R11 can be formed in the insulating layer 61, the residual material remaining on the surface of the insulating layer 61 can be reliably removed. Therefore, the magnetoresistance effect elements 40 adjacent to each other along the X direction can be electrically separated reliably from each other.

As described above, in this embodiment, a magnetic memory device which can reliably prevent electrical conduction between adjacent memory cells 30 can be obtained.

### Second Embodiment

Next, the second embodiment will be described. Note that the basic items are similar to those of the first embodiment, and the description of the items already discussed in the first embodiment will be omitted.

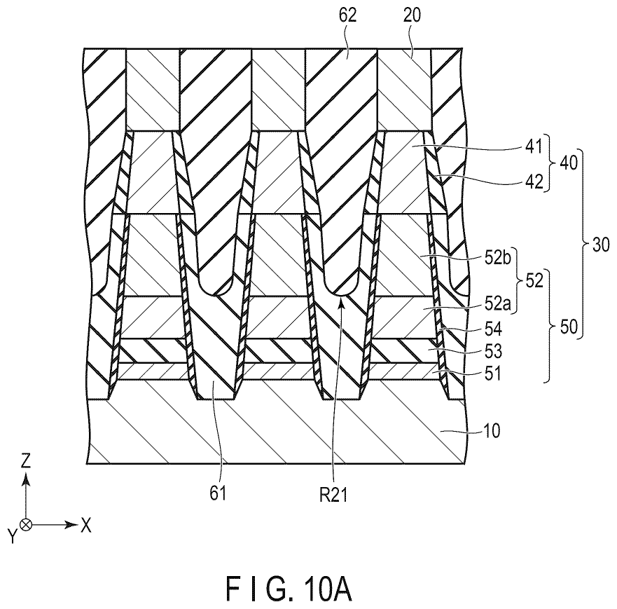

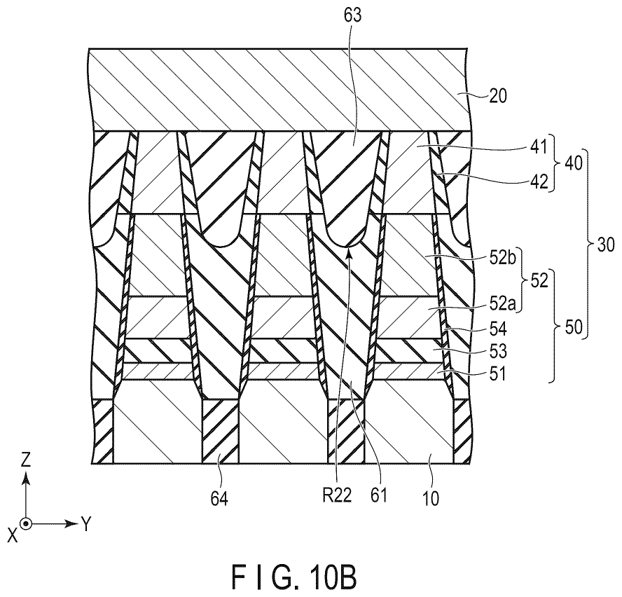

FIGS. 10A and 10B are cross-sectional views schematically illustrating a detailed configuration of a magnetic memory device of this embodiment. FIG. 10A is a cross-sectional view taken along the X direction, and FIG. 10B is a sectional view taken along the Y direction.

As shown in FIG. 10A, according to this embodiment, as in the case of the first embodiment, the sidewall insulating layer 42 of the magnetoresistance effect element 40 included in the first memory cell 30 and the sidewall insulating layer 42 of the magnetoresistance effect element 40 included in the second memory cell 30 are spaced apart from each other along the X direction. That is, the sidewall insulating layers 42 of the magnetoresistance effect elements 40 that are adjacent to each other along the X direction are spaced apart from each other (separated from each other) along the X direction.

As shown in FIG. 10B, according to this embodiment, unlike the case of the first embodiment, the sidewall insulating layer 42 of the magnetoresistance effect element 40 included in the first memory cell 30 and the sidewall insulating layer 42 of the magnetoresistance effect element 40 included in the third memory cell 30 are spaced apart from each other along in the Y direction. That is, the sidewall insulating layers 42 of the magnetoresistance effect elements 40 that are adjacent to each other along the Y direction are spaced apart from each other (separated from each other) along the Y direction.

As shown in FIG. 10A, in this embodiment as well, as in the case of the first embodiment, the portion of the insulating layer 61, which is located between the selector 50 included in the first memory cell 30 and the selector 50 included in the second memory cell 30 has a recess portion (first recess portion) R21 recessed in the Z direction. That is, the portion of the insulating layer 61 located between the selectors 50 that are adjacent to each other along the X direction has a recess portion R21. The recess portion R21 in this embodiment is basically the same as the recess portion R11 in the first embodiment.

As shown in FIG. 10B, the portion of the insulating layer 61 located between the selector 50 included in the first memory cell 30 and the selector 50 included in the third memory cell 30 has a recess (second recess portion) R22 that is recessed in the Z direction. That is, the portion of the insulating layer 61 located between the selectors 50 that are adjacent to each other along the Y direction has a recess portion R22.

As shown in FIGS. 10A and 10B, the depth of the recess portion R21 is greater than the depth of the recess portion R22. Further, the depth of the recess portion R22 in this embodiment is greater than the depth of the recess portion R12 in the first embodiment.

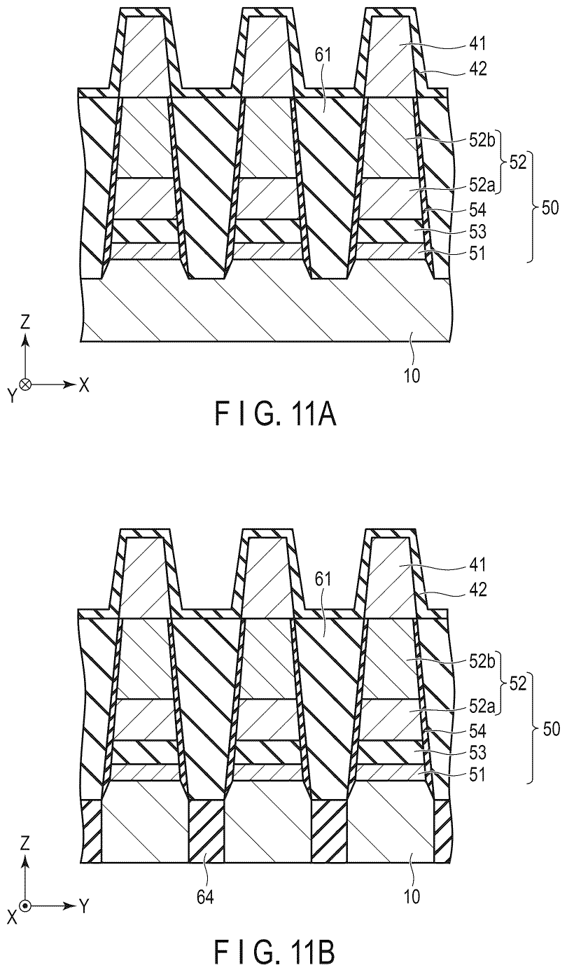

Next, a method of manufacturing the magnetic memory device according to this embodiment will be described with reference to FIGS. 11A and 11B to 16A and 16B. FIGS. 11A to 16A are cross-sectional views taken along the X direction, and FIGS. 11B to 16B are cross-sectional views taken along the Y direction.

First, processing steps similar to those in FIGS. 4A and 4B and FIGS. 5A and 5B of the first embodiment are performed, and thus such a configuration as shown in FIGS. 5A and 5B is formed.

Next, as shown in FIGS. 11A and 11B, the hard mask 71 formed in the processing step of FIGS. 5A and 5B is used as a mask and the magnetoresistance effect element layer 41L is etched using IBE. Thus, the pattern of the magnetoresistance effect element main body 41 is formed. Then, a sidewall insulating layer 42 is formed so as to cover the magnetoresistance effect element main body 41 and the insulating layer 61.

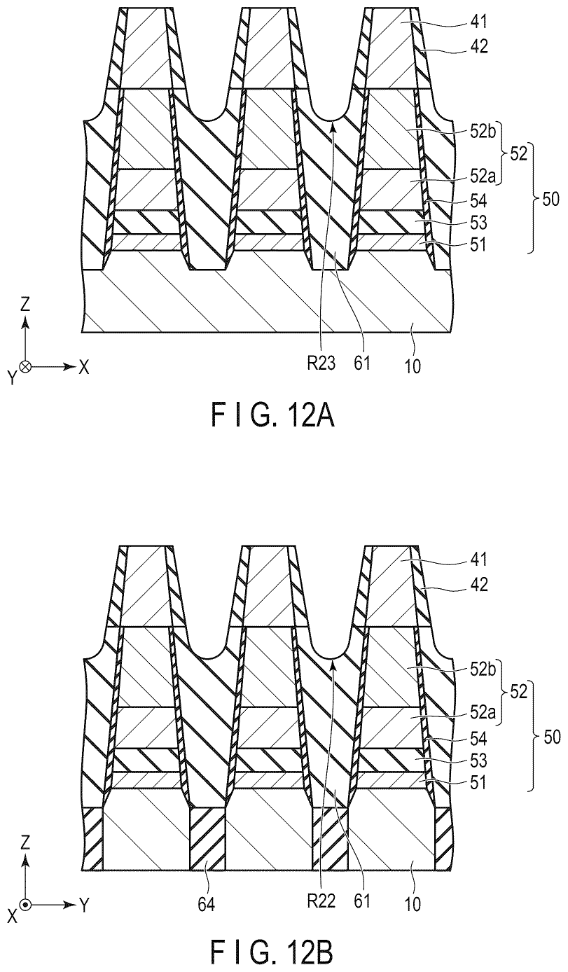

Next, as shown in FIGS. 12A and 12B, the configuration obtained in the step of FIGS. 11A and 11B is subjected to an etching process, for example, RIE. As a result, the sidewall insulating layer 42 formed on the upper surface of the magnetoresistance effect element main body 41 and the upper surface of the insulating layer 61 are removed. Further, recess including the recess portion R22 and recess portion R23 are formed in the insulating layer 61. With this etching process, the residual material remaining on the surface of the insulating layer 61 can be removed.

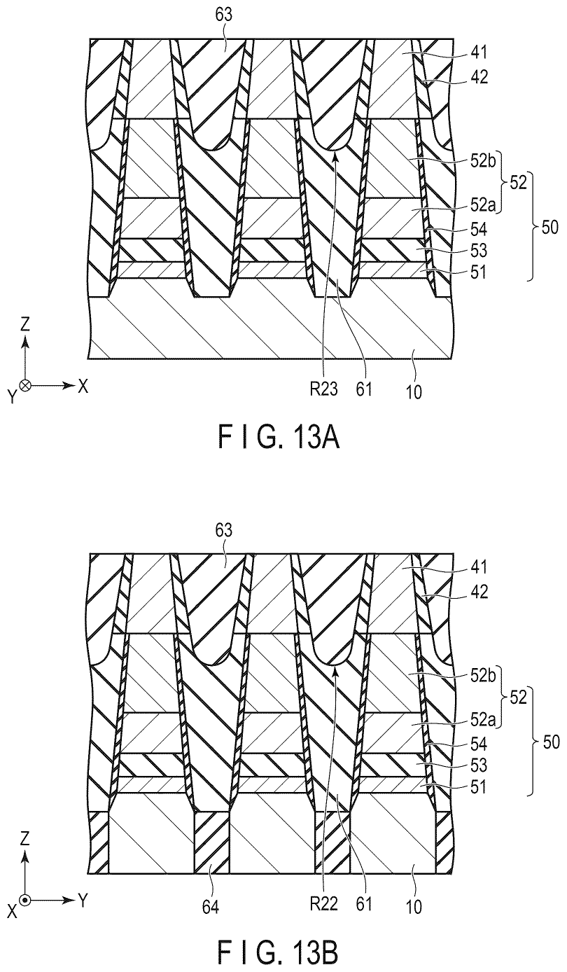

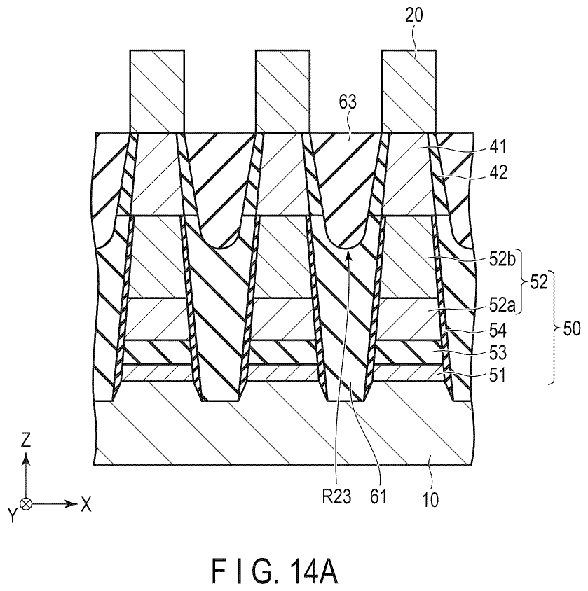

Next, as shown in FIGS. 13A and 13B, an insulating layer 63 is formed on the configuration obtained in the processing step of FIGS. 12A and 12B, and then the insulating layer 63 is planarized.

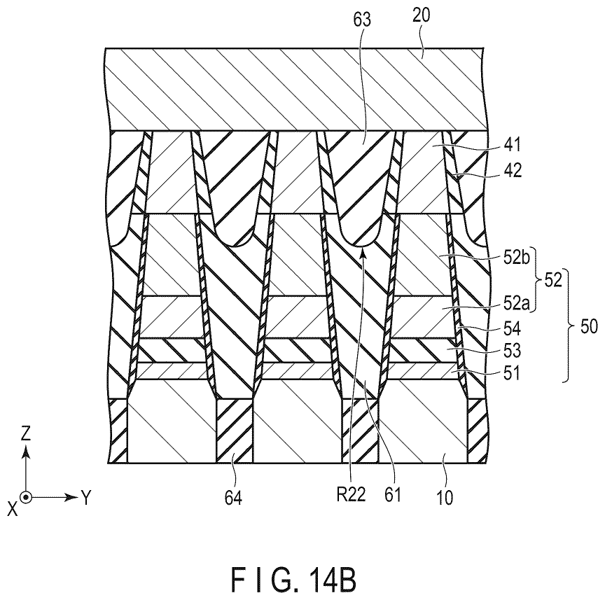

Subsequently, as shown in FIGS. 14A and 14B, a plurality of upper wiring lines 20 are formed on the configuration obtained in the processing step of FIGS. 13A and 13B.

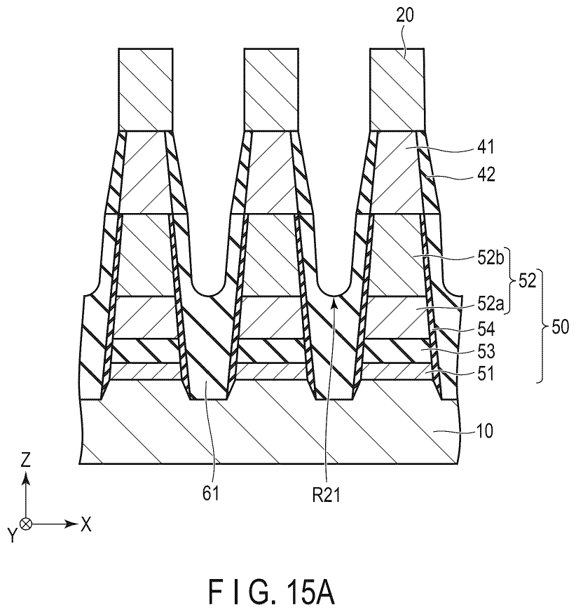

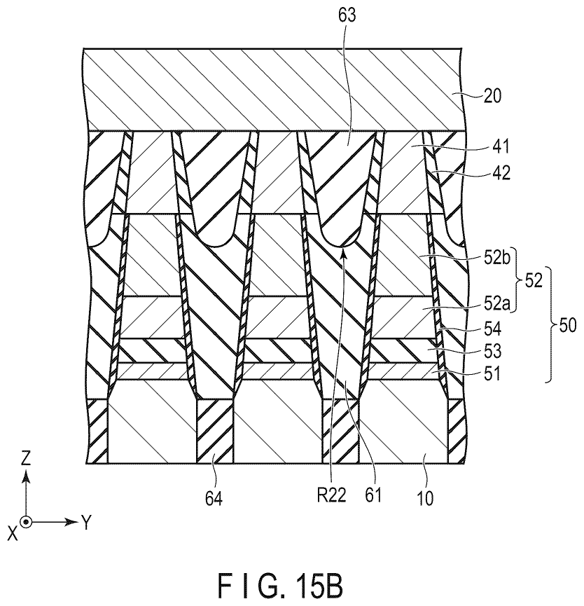

Then, as shown in FIGS. 15A and 15B, the insulating layer 63 and the insulating layer 61 are subjected to etching by RIE or the like, using the upper wiring lines 20 as a mask. The conditions for the etching rates at this time are similar to those described in the step of FIG. 8A and FIG. 8B in the first embodiment. Thus, a sufficiently deep recess portion R21 is formed in the insulating layer 61. With this configuration, even if some residual material remains after the step of FIG. 12A and FIG. 12B, such residual material can be reliably removed.

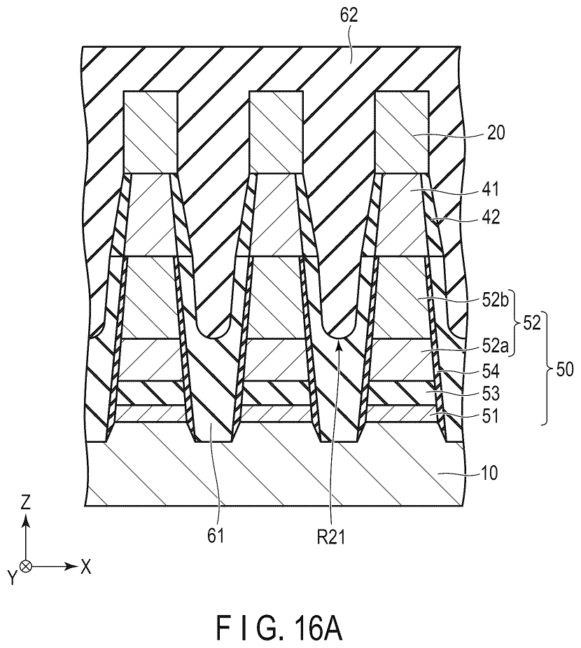

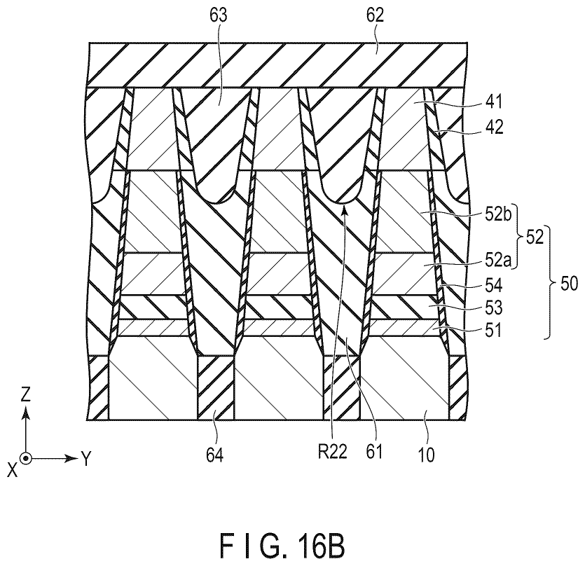

Next, as shown in FIGS. 16A and 16B, an insulating layer 62 is formed on the configuration obtained in the step of FIGS. 15A and 15B, and the recess portion R21 is filled with the insulating layer 62.

Thereafter, the insulating layer 62 is planarized, and thus a magnetic memory device having such a configuration as shown in FIGS. 10A and 10B can be formed.

As described above, in this embodiment as well, it is possible to reliably separate adjacent upper wiring line 20 from each other, and to reliably remove any residual material remaining on the surface of the insulating layer 61. Therefore, as in the first embodiment, it is possible to reliably electrically separate magnetoresistance effect elements 40 that are adjacent to each other along the X direction. Further, in the embodiment, the recess portion R22 and recess portion R23 are formed in the insulating layer 61 in the processing step shown in FIGS. 12A and 12B, it is possible to more effectively remove residues remaining on the surface of the insulating layer 61.

As described above, in this embodiment as well, it is possible to obtain a magnetic memory device which can reliably prevent electrical conduction between adjacent memory cells 30.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A magnetic memory device comprising:
a first lower wiring line and a second lower wiring line, each extending along a first direction and being adjacent to each other;
a first upper wiring line and a second upper wiring line, each extending along a second direction which intersects the first direction and being adjacent to each other;
a first memory cell provided between the first lower wiring line and the first upper wiring line;
a second memory cell provided between the first lower wiring line and the second upper wiring line; and
a third memory cell provided between the second lower wiring line and the first upper wiring line,
wherein
each of the first, second, and third memory cells includes a structure in which a magnetoresistance effect element and a switching element provided on a lower layer side of the magnetoresistance effect element are stacked in a third direction which intersects the first and second directions,
the magnetoresistance effect element includes a magnetoresistance effect element main body and a sidewall insulating layer provided on a side wall of the magnetoresistance effect element main body, and
the sidewall insulating layer of the magnetoresistance effect element included in the first memory cell and the sidewall insulating layer of the magnetoresistance effect element included in the second memory cell are spaced apart from each other along the first direction.

2. The device of claim 1, wherein
the sidewall insulating layer of the magnetoresistance effect element included in the first memory cell and the sidewall insulating layer of the magnetoresistance effect element included in the third memory cell are continuously provided along the second direction.

3. The device of claim 1, wherein
the sidewall insulating layer of the magnetoresistance effect element included in the first memory cell and the sidewall insulating layer of the magnetoresistance effect element included in the third memory cell are spaced apart from each other along the second direction.

4. The device of claim 1, wherein
the sidewall insulating layer contains silicon nitride.

5. The device of claim 1, further comprising:
a first insulating layer which surrounds a side surface of the switching element included in each of the first, second, and third memory cells,
wherein
a portion of the first insulating layer, which is located between the switching element included in first memory cell and the switching element included in the second memory cell has a first recess portion recessed in the third direction.

6. The device of claim 5, wherein
a portion of the first insulating layer, which is located between the switching element included in the first memory cell and the switching element included in the third memory cell has a second recess portion recessed in the third direction, and
a depth of the first recess portion is greater than a depth of the second recess portion.

7. The device of claim 5, wherein
the first insulating layer is formed of a material different from a material of the sidewall insulating layer.

8. The device of claim 5, further comprising:
a second insulating layer including a portion which fills the first recess portion.

9. The device of claim 8, wherein
the second insulating layer further includes a portion located between the magnetoresistance effect element included in the first memory cell and the magnetoresistance effect element included in the second memory cell.

10. The device of claim 9, wherein
the second insulating layer further includes a portion located between the first upper wiring line and the second upper wiring line.

11. The device of claim 1, wherein
the magnetoresistance effect element includes a first magnetic layer having a variable magnetization direction, a second magnetic layer having a fixed magnetization direction, and a non-magnetic layer provided between the first magnetic layer and the second magnetic layer.

12. The device of claim 1, wherein
the switching element includes a bottom electrode, a top electrode, and a switching material layer provided between the bottom electrode and the top electrode.

13. The device of claim 12, wherein
the top electrode of the switching element functions as a bottom electrode for the magnetoresistance effect element, as well.

14. The device of claim 12, wherein
the switching element has a characteristic of changing from an off state to an on state when a voltage equal to or higher than a threshold voltage is applied between the bottom electrode and the top electrode.
